(19) United States
(12) Patent Application Publication
(10) Pub. No.: US 2026/0096220 A1
(43) Pub. Date: Apr. 2, 2026

(54) LATERAL ELECTROSTATIC DISCHARGE DEVICE WITH NANOSHEET GATES

(71) Applicant: INTERNATIONAL BUSINESS MACHINES CORPORATION, ARMONK, NY (US)

(72) Inventors: Robert Gauthier, Williston, VT (US); Anindya Nath, Watervliet, NY (US); Masoud Zabihi, Schenectady, NY (US); Anthony I-Chih Chou, Guilderland, NY (US)

(21) Appl. No.: 18/900,584

(22) Filed: Sep. 27, 2024

(51) Int. Cl. H01L 27/02; H01L 21/762; H01L 21/765; H01L 21/8249; H01L 29/06; H01L 29/423; H01L 29/66; H01L 29/735; H01L 29/775; H01L 29/786

(52) U.S. Cl. CPC H10D 89/711; H10D 10/061; H10D 10/60; H10D 30/014; H10D 30/43; H10D 30/6735; H10D 30/6757; H10D 62/106; H10D 62/121; H10D 84/0109; H10D 84/038; H10W 10/014; H10W 10/051; H10W 10/17; H10W 10/50

(57) ABSTRACT

A semiconductor device includes a guardring including a first doped region and a first contact over the first doped region, a base including a second doped region and a second contact over the second doped region, a collector including a third doped region and a third contact over the third doped region, and an emitter including a fourth doped region and a fourth contact over the fourth doped region. The emitter, the collector, the base, and the guardring are separated on a backside of the semiconductor device via shallow trench isolation (STI) or floating gates.

### BACKGROUND

### Technical Field

The present disclosure generally relates to semiconductors, and more particularly, to semiconductors with nanosheet gates structure, and methods of creation thereof.

### Description of Related Art

The continuous miniaturization of transistors and their increasing density on chips are hallmark innovations in the semiconductor industry, closely following Moore's Law. This trend has enabled transistors to shrink to nanometer scales, allowing millions, and even billions, to be integrated onto a single chip. This advancement significantly boosts computational power and energy efficiency. The evolution towards system-on-chip architectures further enhances these capabilities by integrating various functionalities, such as processing and sensing, into a single chip.

### SUMMARY

According to an embodiment, a semiconductor device includes a guardring having a first doped region and a first contact over the first doped region, a base including a second doped region and a second contact over the second doped region, a collector including a third doped region and a third contact over the third doped region, and an emitter including a fourth doped region and a fourth contact over the fourth doped region. The emitter, the collector, the base, and the guardring are separated on a backside of the semiconductor device via shallow trench isolation (STI) or floating gates.

In an embodiment, the semiconductor device is a lateral N-type/P-type/N-type (LNPN) device, or a lateral P-type/N-type/P-type (LPNP) device.

In an embodiment, the semiconductor device includes an interlayer dielectric (ILD) above the semiconductor device, and an N-well region and a P-well region below the semiconductor device.

In an embodiment, each of the base, the emitter, the collector and the guardring further includes a spacer layer over upper portions of sidewalls of the set of gate regions, and an inner spacer layer over lower portions of the sidewalls of the set of gate regions.

In an embodiment, each of the base, the emitter, the collector and the guardring further includes a plurality of nano-sheet gates between the corresponding doped region and the set of gate regions, and a set of gate regions surrounding the corresponding doped region.

In an embodiment, the plurality of nano-sheet gates includes alternative layers extended horizontally between the corresponding doped region and the set of gate regions.

In an embodiment, the alternative layers include silicon.

According to an embodiment, a method of fabricating a semiconductor device includes forming a guardring including a first doped region and a first contact over the first doped region, forming a base including a second doped region and a second contact over the second doped region, forming a collector including a third doped region and a third contact over the third doped region, forming an emitter including a fourth doped region and a fourth contact over the fourth doped region, and separating the emitter, the collector, the base, and the guardring on a backside of the semiconductor device via shallow trench isolation (STI) or floating gates.

In an embodiment, the semiconductor device is a lateral N-type/P-type/N-type (LNPN) device, or a lateral P-type/N-type/P-type (LPNP) device.

In an embodiment, the method includes forming an interlayer dielectric (ILD) above the semiconductor device, and forming an N-well region and a P-well region below the semiconductor device.

In an embodiment, forming each of the base, the emitter, the collector and the guardring further includes forming a spacer layer over upper portions of sidewalls of the set of gate regions; and forming an inner spacer layer over lower portions of the sidewalls of the set of gate regions.

In an embodiment, forming each of the base, the emitter, the collector and the guardring further including forming plurality of nano-sheet gates extended horizontally between the corresponding doped region and the set of gate regions, and forming a set of gate regions surrounding the corresponding doped region.

According to an embodiment, a semiconductor device includes a guardring including a first doped region and a first contact over the first doped region, a base including a second doped region and a second contact over the second doped region, a collector including a third doped region and a third contact over the third doped region; and an emitter including a fourth doped region and a fourth contact over the fourth doped region. The collector, the base, and the guardring are separated on a backside of the semiconductor device via shallow trench isolation (STI), and the emitter and the collector are separated on the backside of the semiconductor device via floating gates.

In an embodiment, the semiconductor device is a lateral N-type/P-type/N-type (LNPN) device, or a lateral P-type/N-type/P-type (LPNP) device.

In an embodiment, the semiconductor device includes an interlayer dielectric (ILD) above the semiconductor device, and an N-well region and a P-well region below the semiconductor device.

In an embodiment, each of the base, the emitter, the collector and the guardring further includes a spacer layer over upper portions of sidewalls of the set of gate regions, and an inner spacer layer over lower portions of the sidewalls of the set of gate regions.

In an embodiment, each of the base, the emitter, the collector and the guardring further includes a plurality of nano-sheet gates between the corresponding doped region and the set of gate regions, and a set of gate regions surrounding the corresponding doped region.

In an embodiment, the plurality of nano-sheet gates comprises alternative layers extended horizontally between the corresponding doped region and the set of gate regions.

In an embodiment, the alternative layers include silicon.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1A illustrates a sideview of a planar complementary metal oxide semiconductor device.

FIG. 1B illustrates exemplary circuitry of the planar complementary metal oxide semiconductor device as shown in FIG. 1A.

FIG. 1C illustrates an I-V chart for the planar complementary metal oxide semiconductor device as shown in FIG. 1A.

FIGS. 1D-1E illustrate schematically an ESD device operation during the normal circuit operation voltage range, ESD operating window during an ESD event, and the failure region.

FIGS. 2A-2B illustrate an electrostatic discharge device, in accordance with an embodiment.

FIGS. 3A-3B illustrate a semiconductor device with non-self-aligned nanosheet gates, in accordance with an embodiment.

FIGS. 4A-4B illustrate a semiconductor device with shallow trench isolation, in accordance with an embodiment.

FIG. 5 illustrates a semiconductor device after the formation of the starting substrate, in accordance with an embodiment.

FIG. 6 illustrates a semiconductor device after the patterning of the nanosheets gates, in accordance with an embodiment.

FIG. 7 illustrates a semiconductor device after the patterning of the gates, in accordance with an embodiment.

FIG. 8 illustrates a semiconductor device after the formation of the spacer, in accordance with an embodiment.

FIG. 9 illustrates a semiconductor device after the recession of the nanosheet gates, in accordance with an embodiment.

FIG. 10 illustrates a semiconductor device after the formation of the interlayer dielectric, in accordance with an embodiment.

FIG. 11 illustrates a semiconductor device after the removal of the dummy gates, in accordance with an embodiment.

FIG. 12 illustrates a semiconductor device after the formation of the gates, in accordance with an embodiment.

FIG. 13 illustrates a semiconductor device after the middle of line processes, in accordance with an embodiment.

FIG. 14 illustrates a block diagram of a method for forming the semiconductor device, in accordance with an embodiment.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together—intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or active changes may be made without departing from the spirit and scope defined by the claims. The description of the embodiments is not limiting. In particular, elements of the embodiments described hereinafter may be combined with elements of different embodiments.

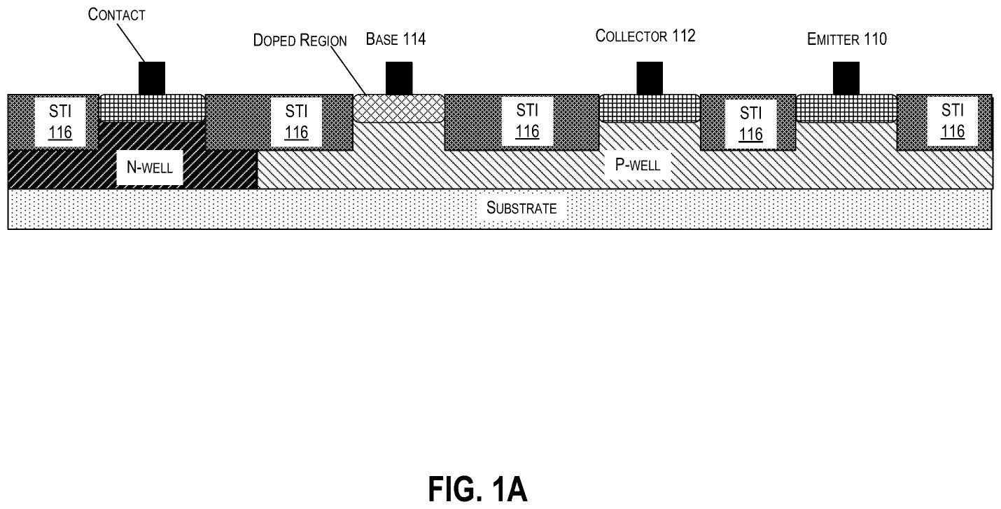

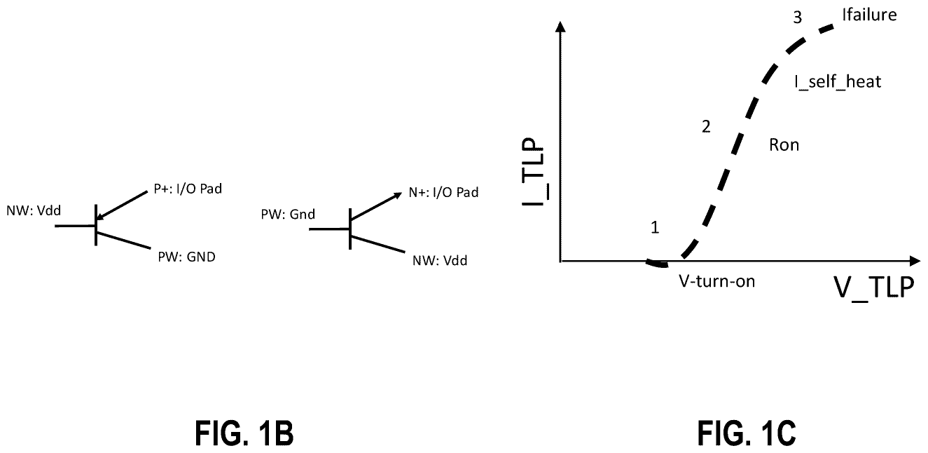

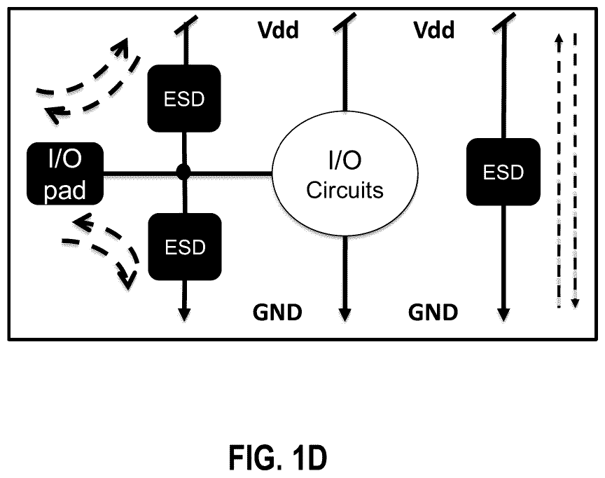

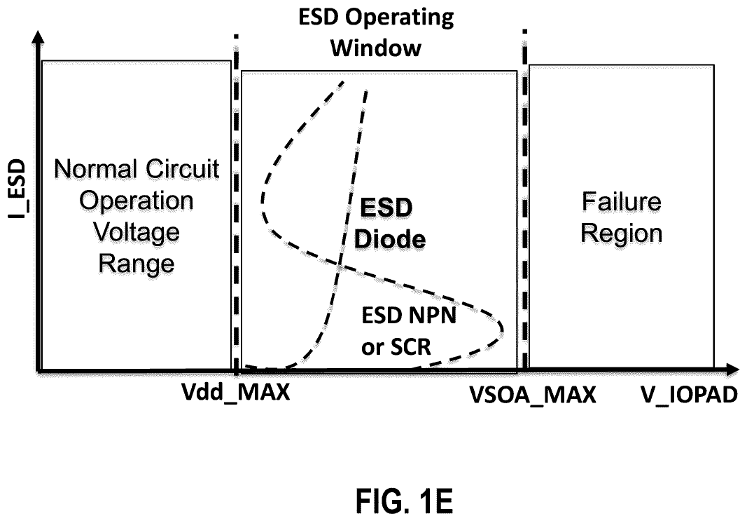

FIG. 1A illustrates a sideview of a planar complementary metal oxide semiconductor device. A planar complementary metal-oxide-semiconductor (CMOS) semiconductor devices are commonly used in integrated circuits. As shown in FIG. 1A, the transistor operates with the current flowing from the emitter 110 to the collector 112, with the base 114 controlling this current flow. In this type of transistor, the emitter 110 is heavily doped with P-type, or N-type impurities to create a high concentration of holes or electrons, which are positive charge carriers/negative charges.

The base 114 is a very thin region between the emitter 110 and collector 112, doped with N-type/P-type impurities, and it regulates the flow of holes/electrons from the emitter 110 to the collector 112. The collector 112, also P-type/N-type, is where the majority of the current exits the transistor, though it is lightly doped compared to the emitter 110 to allow efficient collection of carriers.

Shallow trench isolation (STI) is a technique that can be used to electrically isolate different components on a semiconductor chip. In the case of a planar CMOS PNP transistor, STI isolates the PNP transistor from adjacent devices, preventing electrical interference and ensuring reliable operation. STI can further isolate the base 114, emitter 110 and collector 112 from each other. STI involves etching shallow trenches into the silicon substrate around the active regions of the transistor, such as the emitter 110, base 114, and collector 112. These trenches are filled with an insulating material, typically silicon dioxide, to create a physical barrier between the transistor and the surrounding areas. This isolation reduces leakage currents, minimizes parasitic capacitance, and improves the overall performance and density of the integrated circuit.

The operation of a planar CMOS PNP transistor involves the movement of holes from the emitter 110 to the collector 112, controlled by the base 114. When a sufficient voltage is applied between the emitter 110 and the base 114, with the emitter 110 more positive than the base 114, holes are injected from the emitter 110 into the base 114. The base 114, being thin and lightly doped, allows most of these holes to diffuse across it and be collected by the collector 112, permitting current to flow through the transistor. The current flow through the collector 112 is much larger than the base current, providing the transistor's amplification property. By controlling the base current, the PNP transistor can switch large currents on or off in the collector-emitter circuit, making it useful in various switching and amplification applications in CMOS circuits.

The use of STI 116 in planar CMOS PNP transistors enhances the device by providing effective isolation between devices, which is essential for complex digital and analog circuits. STI 116 also can improve the electrical characteristics of the transistor by reducing unwanted interactions with neighboring devices, lowering leakage currents, and minimizing the risk of latch-up, which is a condition where unintended current paths create short circuits within the chip.

FIG. 1B illustrates exemplary circuitry of the planar complementary metal oxide semiconductor device as shown in FIG. 1A. FIG. 1C illustrates an I-V chart for the planar complementary metal oxide semiconductor device as shown in FIG. 1A. FIGS. 1D-1E illustrate schematically how an ESD device operates during the normal circuit operation voltage range, ESD operating window during an ESD event, and the failure region.

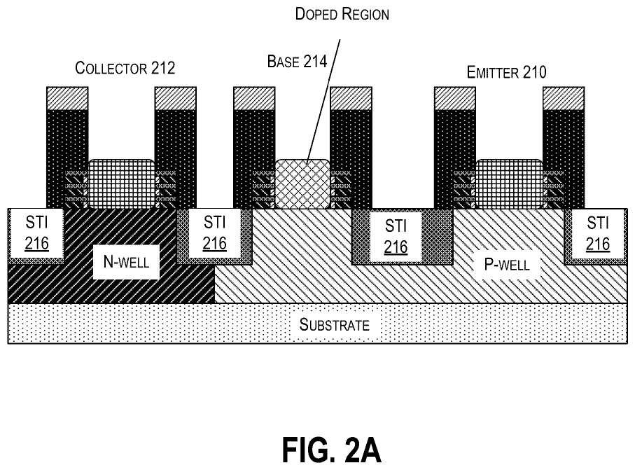

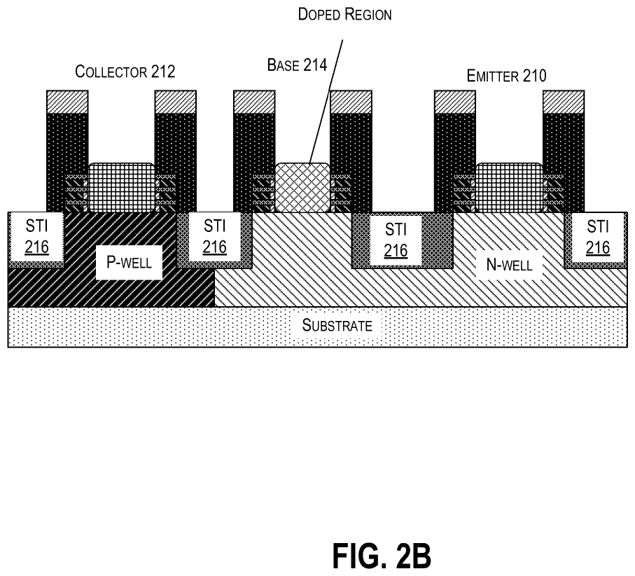

FIG. 2 illustrates an electrostatic discharge device, in accordance with an embodiment. A conventional vertical PNP electrostatic discharge (VPNP ESD) protection device can include STI 216 and be used to protect sensitive components in an integrated circuit from damage due to electrostatic discharge events. In this configuration, the PNP transistor is designed in a vertical layout, where the current flows vertically through the different regions of the device rather than horizontally, as is the case in planar transistors. In a vertical PNP transistor, the structure is built with the emitter 210, base 214, and collector 212 regions stacked on top of each other in a vertical orientation within the silicon substrate. The emitter 210 is at the top, the base 214 is in the middle, and the collector 212 is at the bottom, extending deeper into the substrate. The emitter 210 is heavily doped with P-type impurities, creating a high concentration of holes, which are the charge carriers in a PNP transistor. Directly below the emitter 210 is the base 214, which is lightly doped with N-type impurities. The base 214 controls the flow of holes from the emitter 210 to the collector 212. The collector 212 is also P-type and is located below the base 214, allowing it to collect the holes that pass through the base.

The STI process can involve etching narrow, shallow trenches into the silicon substrate around the active regions of the transistor, particularly the emitter 210, base 214, and collector 212. These trenches are filled with an insulating material, usually silicon dioxide, which electrically isolates the vertical PNP transistor from other components on the chip. This isolation is salient for preventing electrical crosstalk, reducing leakage currents, and ensuring that the ESD protection device functions independently and effectively.

During an ESD event, the vertical PNP transistor activates to provide a low-resistance path for the discharge current, diverting it away from sensitive circuitry and thereby protecting the chip. The vertical structure can handle higher current densities due to the larger cross-sectional area available for current flow in the vertical direction. The STI 216 ensures that the current is confined to the intended path, preventing it from affecting neighboring structures and maintaining the integrity of the ESD protection. However, such devices as shown in FIG. 1 and FIG. 2 cannot be sued for lateral PNP (or lateral NPN) ESD device structures.

Disclosed is a semiconductor device with lateral PNP (or NPN) ESD device structure. The disclosed semiconductor device meets specific standards and requirements for the Input/Output (I/O) types that are used in the design of semiconductor circuits and can be used to safeguard sensitive electronic components from damage caused by sudden electrostatic discharges, which can occur during manufacturing, assembly, or even regular device operation.

The disclosed semiconductor device can include lateral bipolar transistors, which can be used in ESD protection circuits due to its ability to handle high current densities and quickly respond to ESD events. Disclosed are two isolation methods that are utilized to ensure the proper functioning and performance of the semiconductor device: STI bound and Floating gate bound.

The STI bound method can use STI to electrically isolate the lateral bipolar transistor from surrounding components in the semiconductor substrate. The floating gate bound method can involve using a floating gate structure to isolate the lateral bipolar transistor.

Accordingly, the teachings herein provide methods and systems of lateral electrostatic discharge device with nanosheet gates. The techniques described herein may be implemented in a number of ways. Example implementations are provided below with reference to the following figures.

### Example Semiconductor Device with Nanosheet Gate Structure

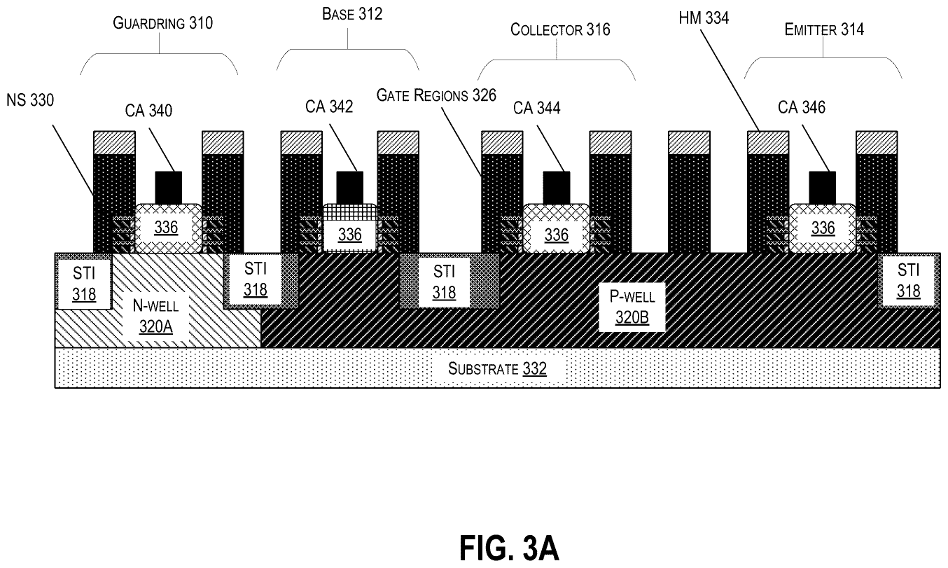

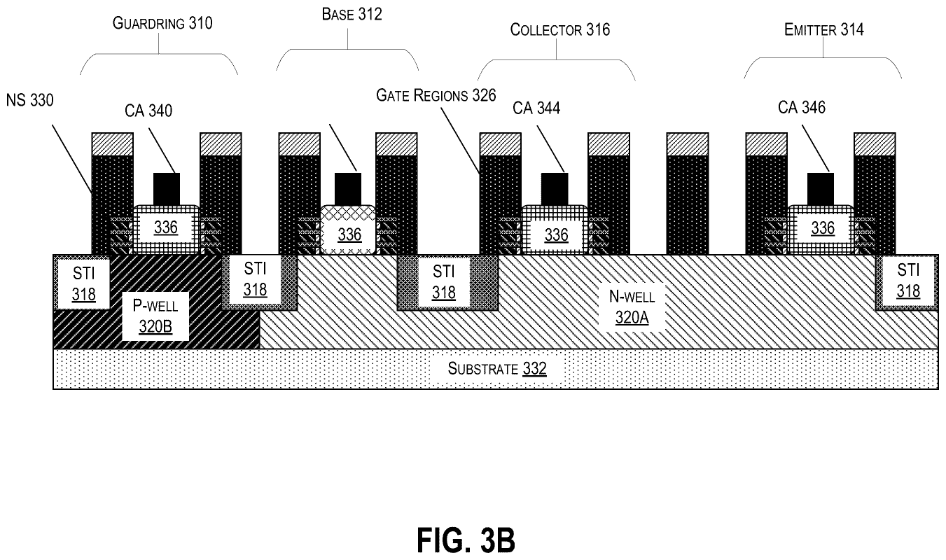

Reference now is made to FIGS. 3A-3B, which is a simplified cross-section view of a semiconductor device, consistent with an illustrative embodiment. More specifically, 3A illustrates a semiconductor device including a guardring 310, a base 312, an emitter 314, a collector 316, shallow trench isolation, STI 318, an interlayer dielectric, an N-well region 320A, a P-well region 320B, gate regions 326, a plurality of nanosheet gates, NS 330, a substrate 332, hard masks, HM 334, and a plurality of doped regions 336.

Each of the N-well region 320A and the P-well region 320B can be created by doping with a type P dopant, which introduces an excess of positive charge carriers (holes), or with a type N dopant, which introduces an excess of negative charge carriers (electrons). An N-well region and a P-well region can form the p-n junction of the semiconductor device. The p-n junction can control the flow of electrical current within the semiconductor device. The p-n junction can be created by doping two adjacent regions, one with a type P dopant, which introduces an excess of positive charge carriers (holes), and the other with a type N dopant, which introduces an excess of negative charge carriers (electrons). At the interface between the P and N regions, a depletion region forms due to the diffusion of electrons from the N region into the P region and the diffusion of holes in the opposite direction. Such a diffusion process continues until the electric field created by the accumulation of charge at the junction balances the diffusion forces, resulting in a zone depleted of free charge carriers. In its natural state, the p-n junction allows current to flow more easily in one direction than in the opposite.

When forward biased, i.e., positive voltage applied to the P side relative to the N side, the depletion region narrows, lowering the barrier for charge carriers to move across the junction, and allowing current to flow through the device. Conversely, when reverse-biased, i.e., negative voltage applied to the P side, the depletion region widens, increasing the barrier for charge movement, and significantly reducing the flow of current. In some embodiments, the N-well region 320A and the P-well region 320B can form on two sides of the STI 318, which can facilitate the control of threshold voltages and channel formation in the semiconductor device.

The STI 318 can electrically isolate different components by filling the trenches with an insulating material, such as silicon dioxide. The STI 318 can prevent electrical interference and crosstalk between adjacent devices, ensuring that each component operates independently without affecting its neighbors.

The guardring 310 can include a first doped region with a first contact, CA 340, placed above it to provide a defined pathway for electrical interaction. The base 312 is formed from a second doped region accompanied by a second contact, CA 342, located on top, similarly facilitating electrical connectivity. The collector 316 includes a third doped region with a third contact, CA 344, positioned above it. The emitter 314 is constructed with a fourth doped region capped by a fourth contact, CA 346, that interfaces with the emitter's electrical output.

Collector 316, base 312, and guardring 310 are electrically isolated from each other through the use of the STI 318 or floating gates. The floating gates, which are electrically isolated and surrounded by a dielectric layer, can be used for specific applications requiring capacitive coupling and more advanced control of electrical properties.

In one embodiment, the semiconductor device is configured as either a lateral N-type/P-type/N-type (LNPN) device, or a lateral P-type/N-type/P-type (LPNP) device. The designation of LNPN or LPNP depends on the arrangement of the doped regions, which dictate the movement of charge carriers and the current flow through the device. These lateral configurations are often used in applications where efficient current flow across the semiconductor is required, such as in amplification circuits and signal switching. In LNPN devices, electrons are the primary charge carriers, while in LPNP devices, holes serve this function. The lateral structure allows these devices to achieve fast switching speeds, making them suitable for use in high-performance electronic systems.

In another embodiment, each of the base 312, emitter 314, collector 316, and guardring 310 incorporates spacer that is positioned over the upper portions of the sidewalls of the gate region. The spacer can facilitate managing the electric fields within the semiconductor device, particularly in the high-performance domains where precise control of the electrical properties is necessary. Additionally, the base 312, emitter 314, collector 316, and guardring 310 include spacer located on the lower portions of the sidewalls of these gate regio. The inner spacer 328 and the spacer 324 can work together to optimize the distribution of electrical fields, reduce parasitic capacitance, and prevent short-channel effects, which can degrade the performance of the transistor at smaller scales. The spacer can further help maintain the structural integrity of the gates, ensuring consistent operation even in advanced semiconductor nodes where high-density integration is required.

The NS 330 can be situated within each of the base 312, emitter 314, collector 316, and guardring 310. The NS 330 can include thin layers of conductive material positioned between the doped regions and the corresponding gate regions. The NS 330 can enhance control over the channel region of the semiconductor device. By using the NS 330, the semiconductor device can achieve greater control over the switching characteristics of the semiconductor device, improving its speed, power efficiency, and scaling potential. In some embodiments, the NS 330 can be arranged to surround the doped regions, ensuring that the flow of current through each component is effectively managed by the gate's switching action.

The NS 330 can feature alternating layers that extend horizontally between the doped regions and the gate regions. The horizontal layers provide a pathway for current while minimizing the overall footprint of the device, allowing for denser integration in advanced semiconductor designs. The alternating layers typically include materials such as silicon, which is favored for its excellent electrical properties and compatibility with conventional semiconductor manufacturing techniques. Silicon's ability to form high-quality junctions with both N-type and P-type materials makes it ideal for use in nano-sheet gate structures, enabling the device to achieve optimal performance across a wide range of applications. The combination of advanced doping techniques, isolation methods, and nano-sheet gate technology, allows the semiconductor device to deliver highly controlled, efficient current flow. Such a combination is particularly well-suited for applications in power amplification, signal switching, and integrated circuits where performance, scaling, and reliability are essential, while it will be understood that the teachings herein can be used in many other applications as well.

The LNPN ESD protection device according to FIG. 3A-3B can operate by providing a controlled path for electrostatic discharge, preventing it from damaging sensitive components in the circuit. The device can is structured with the emitter 314, collector 316, base 312, and guardring 310 positioned laterally from one side to the other, e.g., from left to right. In this setup, the STI 318 is present between the base 312, collector 316, and guardring 310, but there is no STI between the emitter 314 and collector 316.

When an ESD event occurs, the NPN ESD protection becomes active. A sudden increase in voltage, typical of an ESD event, forward-biases the base-emitter junction. The current is injected from the emitter 314 into the base 312, which is lightly doped and thin, allowing electrons to move across the base 312 and reach the collector 316. Due to the absence of STI between the emitter 314 and collector 316, there is a direct low-resistance path for the electrons, allowing high current to flow from the emitter 314 through the base 312 and into the collector 316 during the discharge event. This current flow is what diverts the potentially harmful ESD current away from the more sensitive components of the integrated circuit.

The base 312 can control the activation of the semiconductor device. Once the base-emitter junction is forward-biased, the electrons are injected from the emitter 314 and are swept across the base 312 into the collector 316, where the ESD current is channeled. The STI 318 between the base 312 and collector 316, as well as between the base 312 and the guardring 310, ensures that the current is confined to the intended regions, preventing leakage into adjacent structures. The guardring 310, isolated by the STI 318, helps manage lateral currents and provides an additional safeguard against current leakage into the neighboring regions.

The collector 316, which is directly connected to the emitter 314 without STI, collects the electrons and allows them to flow out of the device, effectively creating a path for the discharge to safely dissipate. In some embodiments, the guardring 310 provides further isolation and protection by confining the current flow and ensuring that it does not interfere with nearby components. This lateral NPN structure allows for efficient current handling during an ESD event, ensuring the device can withstand and safely dissipate the electrostatic discharge without damaging the protected circuit components.

It should be noted that, in the lateral NPN ESD device shown in FIG. 3A, the guardring 310 is above the N-well region 320A and the base 312, the collector 316 and the emitter 314 are above the P-well region 320B. Further, the doped regions of the guardring 310 and the emitter 314 are N-type doped regions and the doped regions of the base 312 and the collector 316 are P-type doped regions.

Reference is now made to FIG. 3B, which illustrates a semiconductor device including a guardring 310, a base 312, an emitter 314, a collector 316, shallow trench isolation, STI 318, an interlayer dielectric, an N-well region 320A, a P-well region 320B, gate regions 326, a plurality of nanosheet gates, NS 330, a substrate 332, hard masks, HM 334, and a plurality of doped regions 336.

It should be noted that, in the lateral PNP ESD device shown in FIG. 3B, the guardring 310 is above the P-well region 320B and the base 312, the collector 316 and the emitter 314 are above the N-well region 320A. Further, the doped regions of the guardring 310 and the emitter 314 are P-type doped regions and the doped regions of the base 312 and the collector 316 are N-type doped regions.

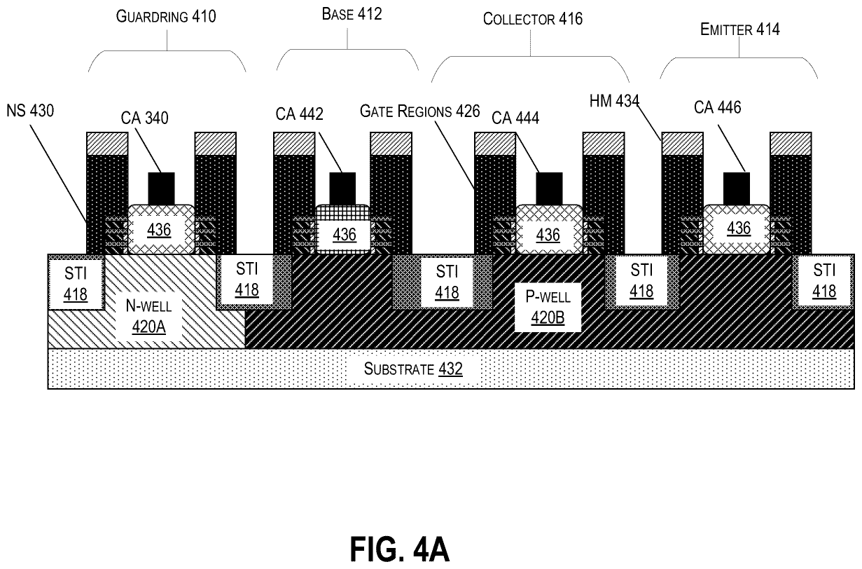

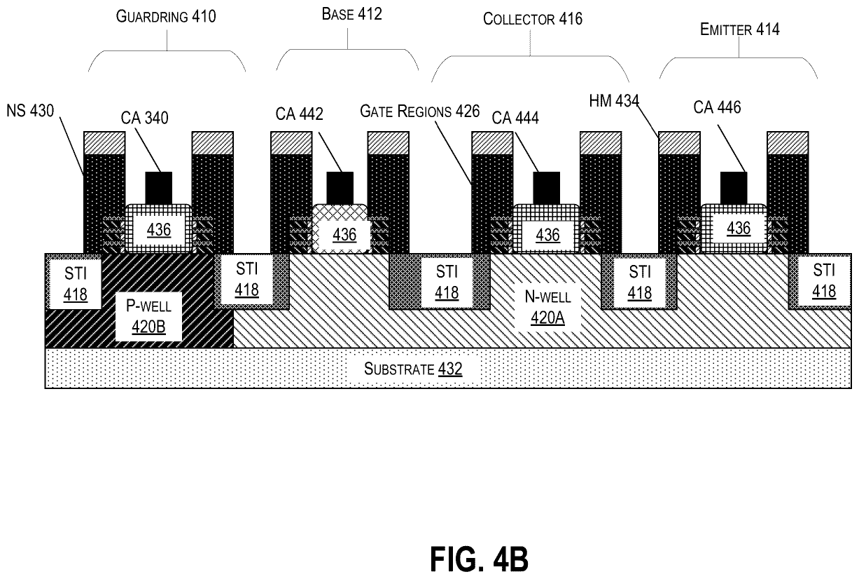

Reference is now made to FIG. 4A, which illustrates a semiconductor device including a guardring 410, a base 412, an emitter 414, a collector 416, shallow trench isolation, STI 418, an interlayer dielectric, an N-well region 422A, a P-well region 422B, gate regions 426, a plurality of nanosheet gates, NS 430, a substrate 432, hard masks, HM 434, and a plurality of doped regions 436. Each of the N-well region 420A and the P-well region 420B can be created by doping with a type P dopant, which introduces an excess of positive charge carriers (holes), or with a type N dopant, which introduces an excess of negative charge carriers (electrons). An N-well region and a P-well region can form the p-n junction of the semiconductor device. The p-n junction can control the flow of electrical current within the semiconductor device. The p-n junction can be created by doping two adjacent regions, one with a type P dopant, which introduces an excess of positive charge carriers (holes), and the other with a type N dopant, which introduces an excess of negative charge carriers (electrons). At the interface between the P and N regions, a depletion region forms due to the diffusion of electrons from the N region into the P region and the diffusion of holes in the opposite direction. Such a diffusion process continues until the electric field created by the accumulation of charge at the junction balances the diffusion forces, resulting in a zone depleted of free charge carriers. In its natural state, the p-n junction allows current to flow more easily in one direction than in the opposite.

When forward biased, i.e., positive voltage applied to the P side relative to the N side, the depletion region narrows, lowering the barrier for charge carriers to move across the junction, and allowing current to flow through the device. Conversely, when reverse-biased, i.e., negative voltage applied to the P side, the depletion region widens, increasing the barrier for charge movement, and significantly reducing the flow of current. In some embodiments, the N-well region 420A and the P-well region 422 can form on two sides of the STI 418, which can facilitate the control of threshold voltages and channel formation in the semiconductor device.

The STI 418 can electrically isolate different components by filling the trenches with an insulating material, such as silicon dioxide. The STI 418 can prevent electrical interference and crosstalk between adjacent devices, ensuring that each component operates independently without affecting its neighbors.

The guardring 410 can include a first doped region 440A, with a first contact, CA 440B, placed above it to provide a defined pathway for electrical interaction. The base 412 is formed from a second doped region 442A, accompanied by a second contact, CA 442B, located on top, similarly facilitating electrical connectivity. The collector 416 includes a third doped region 446A, with a third contact, CA 446B, positioned above it. The emitter 414 is constructed with a fourth doped region 444A, capped by a fourth contact, CA 444B, that interfaces with the emitter's electrical output.

The structural arrangement of the components can ensure that the emitter 414, collector 416, base 412, and guardring 410 are electrically isolated from each other through the use of the STI 418 or floating gates. The floating gates, which are electrically isolated and surrounded by a dielectric layer, can be used for specific applications requiring capacitive coupling and more advanced control of electrical properties.

In one embodiment, the semiconductor device is configured as either a lateral negative-positive-negative (LNPN) device or a lateral positive-negative-positive (LPNP) device. The designation of LNPN or LPNP depends on the arrangement of the doped regions, which dictate the movement of charge carriers and the current flow through the device. These lateral configurations are often used in applications where efficient current flow across the semiconductor is required, such as in amplification circuits and signal switching. In LNPN devices, electrons are the primary charge carriers, while in LPNP devices, holes serve this function. The lateral structure allows these devices to achieve fast switching speeds, making them suitable for use in high-performance electronic systems.

In another embodiment, each of the base 412, emitter 414, collector 416, and guardring 410 incorporates spacer that is positioned over the upper portions of the sidewalls of the NS 430. The spacer can facilitate managing the electric fields within the semiconductor device, particularly in the high-performance domains where precise control of the electrical properties is necessary. Additionally, the base 412, emitter 414, collector 416, and guardring 410 include spacer located on the lower portions of the sidewalls of these NS 430. The inner spacer 428 and the spacer can work together to optimize the distribution of electrical fields, reduce parasitic capacitance, and prevent short-channel effects, which can degrade the performance of the transistor at smaller scales. The spacer can further help maintain the structural integrity of the gates, ensuring consistent operation even in advanced semiconductor nodes where high-density integration is required.

The NS 430 can be situated within each of the base 412, emitter 414, collector 416, and guardring 410. The NS 430 can include thin layers of conductive material positioned between the doped regions and the corresponding gate regions. The NS 430 can enhance control over the channel region of the semiconductor device. By using the NS 430, the semiconductor device can achieve greater control over the switching characteristics of the semiconductor device, improving its speed, power efficiency, and scaling potential. In some embodiments, the NS 430 can be arranged to surround the doped regions, ensuring that the flow of current through each component is effectively managed by the gate's switching action.

The NS 430 can feature alternating layers that extend horizontally between the doped regions and the gate regions. The horizontal layers provide a pathway for current while minimizing the overall footprint of the device, allowing for denser integration in advanced semiconductor designs. The alternating layers typically include materials such as silicon, which is favored for its excellent electrical properties and compatibility with conventional semiconductor manufacturing techniques. Silicon's ability to form high-quality junctions with both N-type and P-type materials makes it ideal for use in nano-sheet gate structures, enabling the device to achieve optimal performance across a wide range of applications. The combination of advanced doping techniques, isolation methods, and nano-sheet gate technology allows the semiconductor device to deliver highly controlled, efficient current flow. Such a combination is particularly well-suited for applications in power amplification, signal switching, and integrated circuits where performance, scaling, and reliability are essential, while it will be understood that many other applications are contemplated as well.

The LNPN ESD protection device according to FIGS. 4A-4B can operate by providing a controlled path for electrostatic discharge, preventing it from damaging sensitive components in the circuit. The device can be structured with the emitter 414, collector 416, base 412, and guardring 410 positioned laterally from one side to the other, e.g., from left to right. In this setup, the STI 418 is present between the base 412, collector 416, emitter 414, and guardring 410.

When the STI 418 is placed between the base 412, collector 416, emitter 414, and guardring 410 in a lateral NPN ESD protection device, each region is physically and electrically isolated by the insulating material, typically silicon dioxide. The STI 418 around these regions prevents direct electrical interaction and confines the current flow during an ESD event. With STI 418 between the emitter 414 and collector 416, the current path is confined, limiting direct current flow between these regions. During an ESD event, electrons injected from the emitter 414 must travel through the base 412 and then into the collector 416, following a more controlled path due to the isolation provided by the STI 418. This configuration ensures that current flows through the designed regions and prevents the formation of a direct low-resistance path between the emitter and collector.

STI 418 between the base 412 and the collector 416, as well as between the base 412 and the guardring 410, creates additional boundaries that prevent current leakage from the base 412 into surrounding regions. The additional boundaries ensures that the current moves only through the intended areas, reducing lateral current spread and parasitic effects that could degrade the performance of the device. The base 412 is thus effectively isolated from both the collector and the guardring. The guardring 410, separated from the base 412 and collector 416 by STI 418, remains electrically isolated, allowing it to function without interference from the adjacent regions. It prevents lateral current flow from reaching other components of the circuit and confines the high-voltage discharge to the active regions of the semiconductor device. The STI 418 between these regions enforces strict boundaries and isolation, reducing the risk of electrical leakage, crosstalk, and unintended current paths. The controlled current flow through the device ensures that the emitter 414, base 412, collector 416, and guardring 410 remain isolated from each other except through the designed conductive paths.

It should be noted that, in the lateral NPN ESD device shown in FIG. 4A, the guardring 410 is above the N-well region 420A and the base 412, the collector 416 and the emitter 414 are above the P-well region 420B. Further, the doped regions of the guardring 410 and the emitter 414 are N-type doped regions and the doped regions of the base 412 and the collector 416 are P-type doped regions.

Reference is now made to FIG. 4B, which illustrates a semiconductor device including a guardring 410, a base 412, an emitter 414, a collector 416, shallow trench isolation, STI 418, an interlayer dielectric, an N-well region 422A, a P-well region 422B, gate regions 426, a plurality of nanosheet gates, NS 430, a substrate 432, hard masks, HM 434, and a plurality of doped regions 436.

It should be noted that, in the lateral PNP ESD device shown in FIG. 4B, the guardring 410 is above the P-well region 422B and the base 412, the collector 416 and the emitter 414 are above the N-well region 422A. Further, the doped regions of the guardring 410 and the emitter 414 are P-type doped regions and the doped regions of the base 412 and the collector 416 are N-type doped regions.

In some embodiments, a floating gate, which is electrically isolated from the other regions of the circuit, surrounds the lateral NPN ESD device. The floating gate can influence the electric field around the transistor through capacitive coupling without being directly connected to the device's electrical pathways. This type of isolation allows for more control over the triggering behavior and electrical properties of the transistor during an ESD event. The floating gate can also modify the electric field distribution, leading to more uniform current flow and improved ESD performance. This method is often used when fine-tuning the voltage threshold for triggering the lateral bipolar transistor during an ESD event is required.

### Example Fabrication of Semiconductor Device with Nanosheet Gate

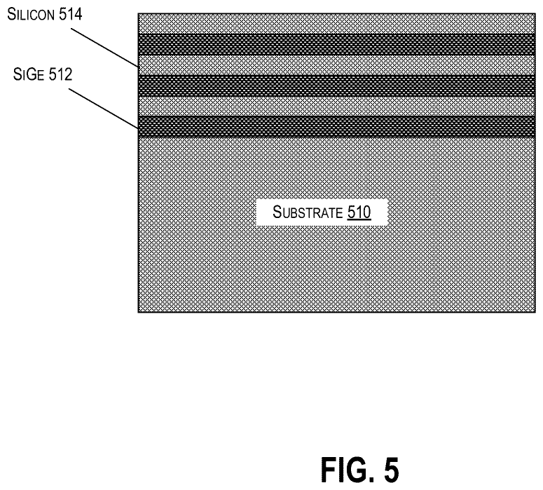

With the foregoing description of an example semiconductor device, it may be helpful to discuss an example process of manufacturing the same. To that end, FIGS. 5-14 illustrate various acts in the manufacture of a semiconductor device, consistent with illustrative embodiments.

Reference now is made to FIG. 5, which is a simplified cross-section view of a semiconductor device, after the preparation of the substrate, consistent with an illustrative embodiment. The semiconductor device can include a substrate 510 and alternating layers of SiGe 512 and silicon 514.

In the illustrative example depicted in FIG. 5, the semiconductor device is depicted as being on silicon as the substrate 510, while it will be understood that other types as the substrate 510 may be used as well, including, without limitation, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs), and quaternary (four elements, e.g., aluminum gallium indium phosphide (AlInGaP)) alloys.

In various embodiments, the substrate 510 can include any suitable material or combination of materials, such as doped or undoped silicon, glass, dielectrics, etc. For example, the substrate may include a silicon-on-insulator (SOI) structure, e.g., with a buried insulator layer, or a bulk material substrate, e.g., with appropriately doped regions, typically referred to as wells. In another embodiment, the substrate may be silicon with silicon oxide, nitride, or any other insulating film on top.

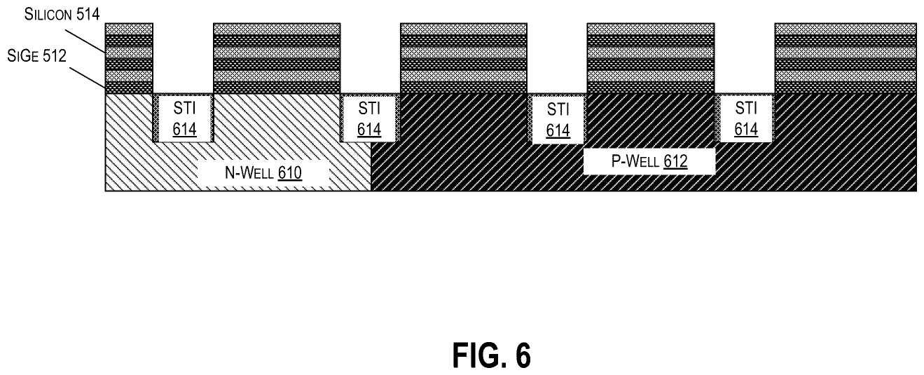

FIG. 6 illustrates a semiconductor device after the patterning of the nanosheet gates, in accordance with some embodiments. In some embodiments, the alternating layers of SiGe 512 and silicon 514 and the substrate are patterned. The patented portions are filled with the STI 614. Portions of the substrate can be doped with an N-type dopant to form an N-well 610, and portions of the substrate can be doped with a P-type dopant to form a P-well 612.

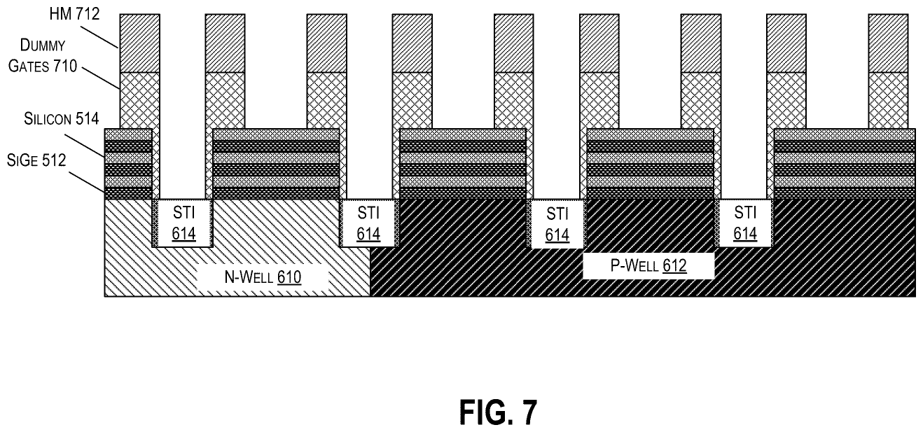

FIG. 7 illustrates a semiconductor device after the patterning of the gates, in accordance with some embodiments. In some embodiments, dummy gates 710 and hard masks, HM 712, are formed over the semiconductor device.

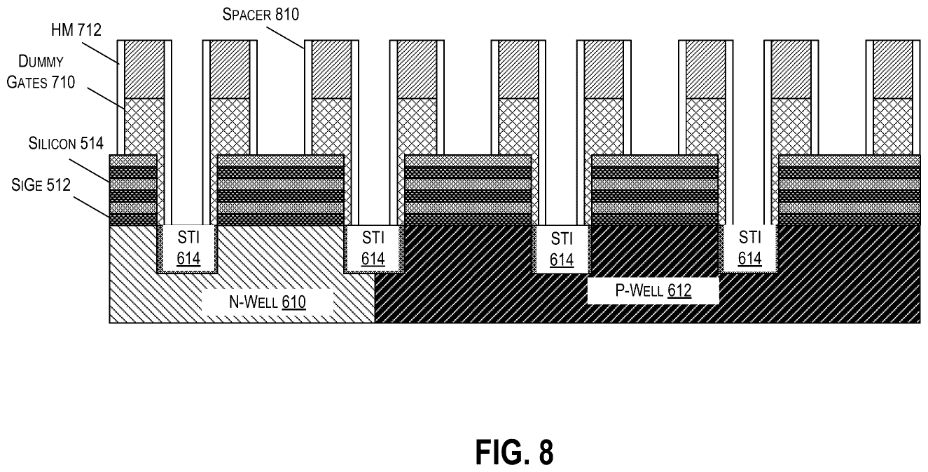

FIG. 8 illustrates a semiconductor device after the formation of the spacer, in accordance with some embodiments. In some embodiments, a spacer 810 is formed over sidewalls of the dummy gates 710 and HM 712. The spacer 810 can be a thin insulating layer or material placed on the sidewalls of the dummy gates 710 and HM 712. In an embodiment, the spacer 810 can allow for control over the channel's conductive properties, including resistance and carrier mobility, which can contribute to improved performance of the semiconductor device. The spacer 810 can be a low-k material. A reactive ion etching (RIE) technique can be performed. Generally, RIE is a dry etching process used in semiconductor device fabrication to remove materials from the surface of a substrate selectively. In some embodiments, RIE can involve the use of reactive ions and plasma to react with and remove specific materials chemically. In an embodiment, the RIE process begins by placing the semiconductor device inside a vacuum chamber. The chamber is then evacuated to create a low-pressure environment. Reactive gases, which can include a combination of a chemically reactive gas and an inert gas, are introduced into the chamber. The chemically reactive gas, such as fluorine-based gases (e.g., CF4, SF6) or chlorine-based gases (e.g., Cl2), can react with the material to be etched, i.e., the second substrate, Si, while the inert gas, e.g., argon, can help to control the ion bombardment.

In some embodiments, radiofrequency or microwave power is applied to create a plasma within the chamber. In such embodiments, power excites the gas molecules, causing them to ionize and form a plasma of reactive ions and electrons. The plasma can include reactive ions that chemically react with the silicon. The reactive ions bombard the substrate surface, break chemical bonds and remove silicon. In various embodiments, the RIE process can be selective, meaning it can mainly affect the target material, i.e., silicon, while leaving other materials, such as masking layers or underlying layers, relatively unaffected.

In some embodiments, to achieve selective etching, an etch mask can be applied on the substrate surface prior to the RIE process. The etch mask protects certain regions from etching, allowing the reactive ions to remove the exposed material selectively. The etching process can be controlled to achieve specific etch profiles, such as vertical sidewalls or tapered structures. Parameters such as gas composition, pressure, power, and process duration are adjusted to achieve the desired etch characteristics. In some embodiments, endpoint detection techniques, such as optical emission spectroscopy or laser interferometry, can be used to determine when the etching process has reached a desired endpoint. This ensures accurate control of the etch depth and prevents over-etching. After the etching process is completed, the substrate can be cleaned to remove any residue or by-products from the etching. Cleaning can involve rinsing with solvents or plasma cleaning to ensure the substrate's surface is free from contaminants.

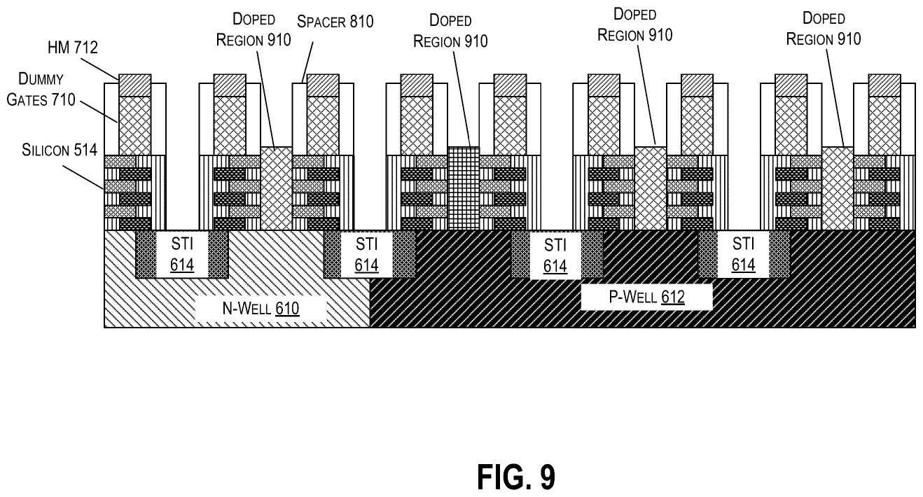

FIG. 9 illustrates a semiconductor device after the recession of the nanosheet gates, in accordance with some embodiments. In some embodiments, doped regions 910 are formed between each two adjacent dummy gates 710 and HM 712 stack. An inner spacer 912 is formed over the sidewalls of the doped regions 910 that are not covered by the alternating layers of SiGe 512 and silicon 514. In some embodiments, the nanosheet gates, NS 914, are formed extending from the doped regions 910 toward the dummy gates 710 and HM 712 stacks.

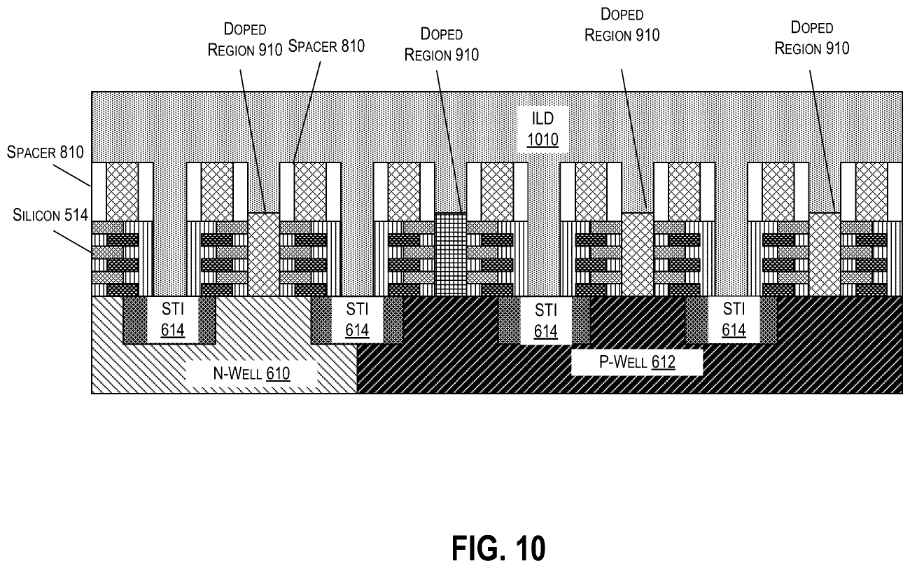

FIG. 10 illustrates a semiconductor device after the formation of interlayer dielectric, in accordance with some embodiments. In some embodiments, an ILD 1010 is formed over the semiconductor device and between the dummy gates 710 and HM 712 stacks.

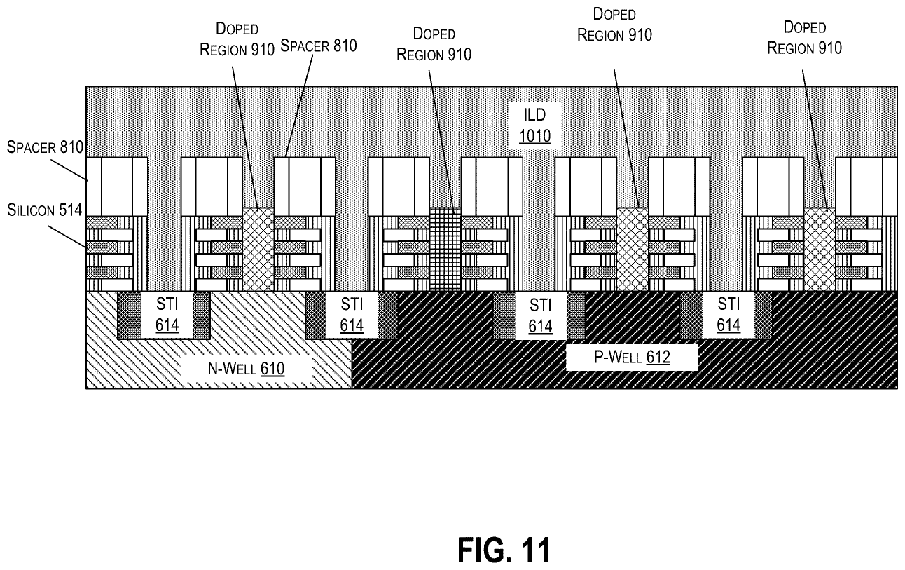

FIG. 11 illustrates a semiconductor device after the removal of the dummy gates, in accordance with some embodiments. In some embodiments, the dummy gates and HM are removed and the SiGe layers of the alternating layers of SiGe 512 and silicon 514 are released, e.g., removed.

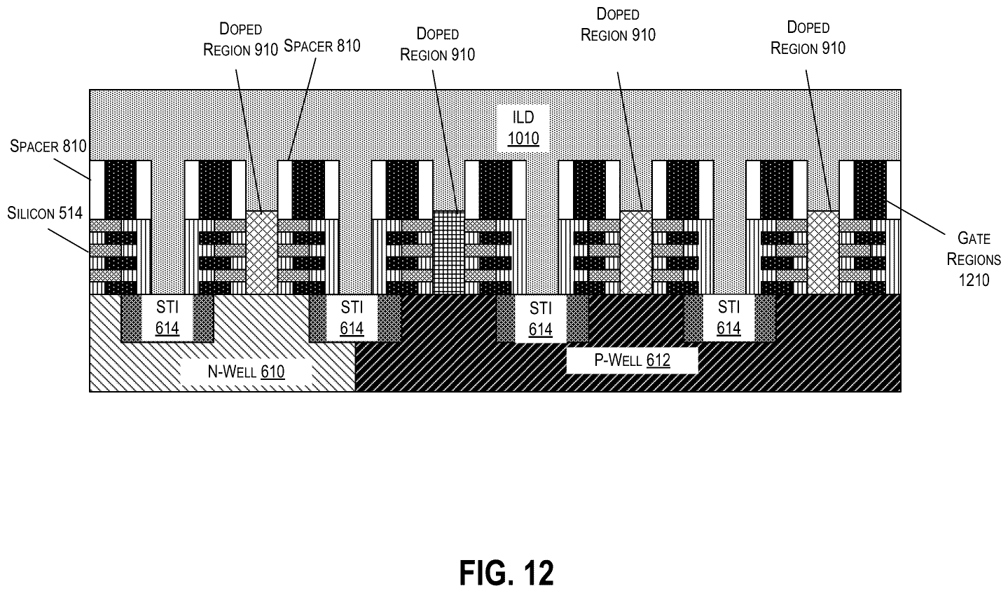

FIG. 12 illustrates a semiconductor device after the formation of the gate regions, in accordance with some embodiments. In some embodiments, the gate regions 1210 are formed. A replacement metal gate (RMG) process can be used to fabricate metal gate electrodes. In some embodiments, RMG can involve the replacement of the SiGe with a metal material, which can offer improved electrical performance and scalability. The metal gates can provide electrostatic control of the channel region, reduce leakage currents, and improve the semiconductor device's performance. In some embodiments, the metal gates can further provide improved control over the work function, enable matching of threshold voltages, and reduce semiconductor device variability.

In various embodiments, the gate regions 1210 serve as control elements that regulate the flow of current through the semiconductor device. The gate regions 1210 can be composed of a conductive material. The gate regions 1210 can control the flow of electric current between the source and drain regions. In addition to acting as a switch, modulating the gate voltage can enable the gate regions 1210 to control the current flowing through the channel region, resulting in amplified output signals.

In an embodiment, the gate regions 1210 can enable the implementation of Boolean active operations, such as AND, OR, and NOT, by controlling the flow of current based on the input voltages. In some embodiments, the gate regions 1210, along with other active device components, can facilitate the miniaturization and integration of electronic circuits. The ability to control the channel region's conductivity through the gate voltage allows for compact and highly efficient circuit designs.

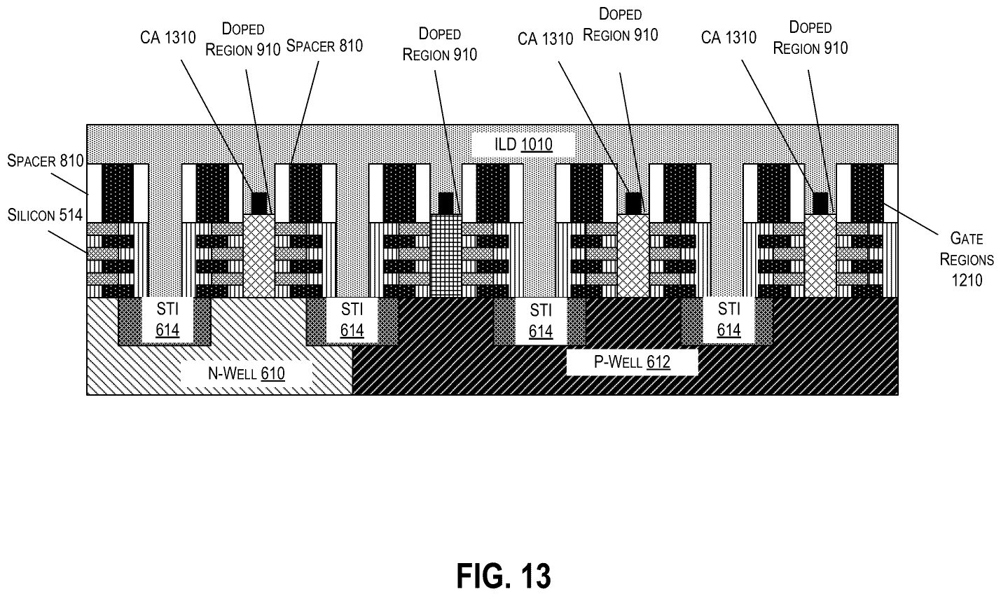

FIG. 13 illustrates a semiconductor device after the middle of line processes, in accordance with some embodiments. In some embodiments, the contacts, CA 1310, are formed over each of the doped regions 910.

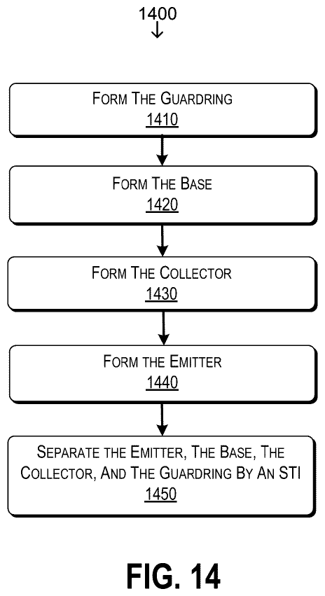

FIG. 14 illustrates a block diagram of a method 1400 for forming the semiconductor device, in accordance with some embodiments. As shown by block 1410, the guardring, including a first doped region and a first contact over the first doped region, is formed.

As shown by block 1420, the base including a second doped region and a second contact over the second doped region is formed.

As shown by block 1430, the collector including a third doped region and a third contact over the third doped region is formed.

As shown by block 1440, the emitter including a fourth doped region and a fourth contact over the fourth doped region, As shown by block 1450, the emitter, the collector, the base, and the guardring are separated on a backside of the semiconductor device via shallow trench isolation (STI) or floating gates.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### Conclusion

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a guardring comprising a first doped region and a first contact over the first doped region;
a base comprising a second doped region and a second contact over the second doped region;
a collector comprising a third doped region and a third contact over the third doped region; and
an emitter comprising a fourth doped region and a fourth contact over the fourth doped region,
wherein the emitter, the collector, the base, and the guardring are separated on a backside of the semiconductor device via shallow trench isolation (STI) or floating gates.

2. The semiconductor device of claim 1, wherein the semiconductor device is a N-type/P-type/N-type (LNPN) device, or a lateral P-type/N-type/P-type (LPNP) device.

3. The semiconductor device of claim 1, further comprising:
an interlayer dielectric (ILD) above the semiconductor device; and
an N-well region and a P-well region below the semiconductor device.

4. The semiconductor device of claim 1, wherein each of the base, the emitter, the collector and the guardring further comprises:
a spacer layer over upper portions of sidewalls of a set of gate regions; and
an inner spacer layer over lower portions of the sidewalls of the set of gate regions.

5. The semiconductor device of claim 1, wherein each of the base, the emitter, the collector and the guardring further comprises:
a plurality of nano-sheet gates between a corresponding doped region and a set of gate regions; and
the set of gate regions surrounding the corresponding doped region.

6. The semiconductor device of claim 5, wherein:
the plurality of nano-sheet gates comprises alternative layers extended horizontally between the corresponding doped region and the set of gate regions.

7. The semiconductor device of claim 6, wherein the alternative layers include silicon.

8. A method of fabricating a semiconductor device, the method comprising:
forming a guardring comprising a first doped region and a first contact over the first doped region;
forming a base comprising a second doped region and a second contact over the second doped region;
forming a collector comprising a third doped region and a third contact over the third doped region;
forming an emitter comprising a fourth doped region and a fourth contact over the fourth doped region; and
separating the emitter, the collector, the base, and the guardring on a backside of the semiconductor device via shallow trench isolation (STI) or floating gates.

9. The method of claim 8, wherein the semiconductor device is a lateral N-type/P-type/N-type (LNPN) device, or a lateral P-type/N-type/P-type (LPNP) device.

10. The method of claim 8, further comprising:
forming an interlayer dielectric (ILD) above the semiconductor device; and
forming an N-well region and a P-well region below the semiconductor device.

11. The method of claim 8, wherein forming each of the base, the emitter, the collector and the guardring further comprises:
forming a spacer layer over upper portions of sidewalls of a set of gate regions; and
forming an inner spacer layer over lower portions of the sidewalls of the set of gate regions.

12. The method of claim 8, wherein forming each of the base, the emitter, the collector and the guardring further comprises:
forming plurality of nano-sheet gates extended horizontally between a corresponding doped region and a set of gate regions; and
forming the set of gate regions surrounding the corresponding doped region.

13. The method of claim 12, wherein the plurality of nano-sheet gates includes silicon.

14. A semiconductor device, comprising:
a guardring comprising a first doped region and a first contact over the first doped region;
a base comprising a second doped region and a second contact over the second doped region;
a collector comprising a third doped region and a third contact over the third doped region; and
an emitter comprising a fourth doped region and a fourth contact over the fourth doped region, wherein:
the collector, the base, and the guardring are separated on a backside of the semiconductor device via shallow trench isolation (STI), and
the emitter and the collector are separated on the backside of the semiconductor device via floating gates.

15. The semiconductor device of claim 14, wherein the semiconductor device is a lateral N-type/P-type/N-type (LNPN) device, or a lateral P-type/N-type/P-type (LPNP) device.

16. The semiconductor device of claim 14, further comprising:
an interlayer dielectric (ILD) above the semiconductor device; and
an N-well region and a P-well region below the semiconductor device.

17. The semiconductor device of claim 14, wherein each of the base, the emitter, the collector and the guardring further comprises:
a spacer layer over upper portions of sidewalls of a set of gate regions; and
an inner spacer layer over lower portions of the sidewalls of the set of gate regions.

18. The semiconductor device of claim 14, wherein each of the base, the emitter, the collector and the guardring further comprises:
a plurality of nano-sheet gates between a corresponding doped region and a set of gate regions; and
the set of gate regions surrounding the corresponding doped region.

19. The semiconductor device of claim 18, wherein:
the plurality of nano-sheet gates comprises alternative layers extended horizontally between the corresponding doped region and the set of gate regions.

20. The semiconductor device of claim 19, wherein the alternative layers include silicon.
